(19) United States
(12) Patent Application Publication
(10) Pub. No.: US 2025/0167093 A1
(43) Pub. Date: May 22, 2025

(54) SEMICONDUCTOR PACKAGE

(71) Applicant: Samsung Electronics Co., Ltd., Suwon-si (KR)

(72) Inventor: DOHOON KIM, Suwon-si (KR)

(21) Appl. No.: 18/794,303

(22) Filed: Aug. 5, 2024

(30) Foreign Application Priority Data
Nov. 16, 2023 (KR) 10-2023-0159576
Dec. 8, 2023 (KR) 10-2023-0177960

(51) Int. Cl. H01L 23/498; H01L 23/00

(52) U.S. Cl. CPC H01L 23/49838; H01L 23/49822; H01L 23/49866; H01L 24/08; H01L 24/16; H01L 24/48; H01L 24/73; H01L 24/32; H01L 2224/081; H01L 2224/16227; H01L 2224/32225; H01L 2224/48227; H01L 2224/73204; H01L 2224/73265; H01L 2924/1815

(57) ABSTRACT

A semiconductor package includes: a package substrate including an insulating layer and a plurality of conductive patterns within the insulating layer and respectively including a wiring portion and a via portion; a semiconductor chip on the package substrate and connected to the plurality of conductive patterns; and a molding member that covers the package substrate and the semiconductor chip. The semiconductor chip is closer to a second edge than to an opposite first edge of the package substrate, the plurality of conductive patterns includes a first conductive pattern overlapping a first side surface of the semiconductor chip in a vertical direction and a second conductive pattern overlapping a second side surface of the semiconductor chip in a vertical direction, and a thickness in the vertical direction of a wiring portion of the first conductive pattern is different from a thickness of a wiring portion of the second conductive pattern.

### CROSS-REFERENCE TO RELATED APPLICATIONS

This application claims priority to and the benefit of Korean Patent Application No. 10-2023-0159576 filed at the Korean Intellectual Property Office on Nov. 16, 2023, and Korean Patent Application No. 10-2023-0177960 filed in the Korean Intellectual Property Office on Dec. 8, 2023, the entire contents of which are incorporated herein by reference.

### BACKGROUND

### 1. Field

The present disclosure relates to a semiconductor package.

### 2. Description of the Related Art

A demand for high capacity, thinning, and miniaturization of an electronic product using a semiconductor device has increased in a semiconductor industry, so that various package technologies related to the demand emerge.

A semiconductor package is an integrated circuit chip implemented in a form suitable for use of an electronic product. For example, the semiconductor package typically includes a semiconductor chip mounted on a printed circuit board (PCB) wherein the semiconductor chip and the printed circuit board (PCB) are electrically connected using a bonding wire or a bump.

Accordingly, to stably connect the semiconductor chip mounted on the printed circuit board (PCB) to wires included in the printed circuit board (PCB), the semiconductor package with improved durability of the wires included in the printed circuit board (PCB) is desirable.

### SUMMARY

Embodiments may provide a semiconductor package with improved reliability and productivity.

A semiconductor package according to an embodiment includes: a package substrate that includes an insulating layer and a plurality of conductive patterns within the insulating layer, each of the plurality of conductive patterns including a respective wiring portion and a respective via portion; a semiconductor chip on the package substrate and connected to the plurality of conductive patterns; and a molding member that covers the package substrate and the semiconductor chip, wherein the semiconductor chip is closer to a second edge than to a first edge of the package substrate opposite to the second edge, wherein the plurality of conductive patterns includes a first conductive pattern overlapping a first side surface of the semiconductor chip in a vertical direction and a second conductive pattern overlapping a second side surface of the semiconductor chip in a vertical direction, and wherein a thickness in the vertical direction of a wiring portion of the first conductive pattern is different from a thickness in the vertical direction of a wiring portion of the second conductive pattern.

A semiconductor package according to another embodiment includes: a package substrate that includes an insulating layer and a plurality of conductive patterns within the insulating layer, each of the plurality of conductive patterns including a respective wiring portion and a respective via portion; a semiconductor chip on the package substrate and connected to the plurality of conductive patterns; and a molding member that covers the package substrate and the semiconductor chip, wherein the semiconductor chip is closer to a second edge of the package substrate than to a first edge of the package substrate opposite to the second edge, wherein conductive patterns disposed at an uppermost portion among the plurality of conductive patterns include a first conductive pattern overlapping a first side surface of the semiconductor chip in a vertical direction, a second conductive pattern overlapping a second side surface of the semiconductor chip in the vertical direction, and a third conductive pattern between the first side surface and the second side surface of the semiconductor chip when viewed in plan view, wherein at least one of a thickness of a wiring portion of the first conductive pattern and a thickness of a wiring portion of the second conductive pattern is greater than a thickness of a wiring portion of the third conductive pattern, and wherein the first conductive pattern includes a first groove recessed toward a bottom surface of the package substrate.

A semiconductor package according to another embodiment includes: a package substrate that includes an insulating layer and a plurality of conductive patterns within the insulating layer, each of the plurality of conductive patterns including a respective wiring portion and a respective via portion; a semiconductor chip on the package substrate and connected to the plurality of conductive patterns; a molding member that covers the package substrate and the semiconductor chip; a bonding pad on a first surface of the package substrate facing the semiconductor chip, the bonding pad being connected to the plurality of conductive patterns; a first connection terminal between the semiconductor chip and the package substrate, the first connection terminal connecting the semiconductor chip to the bonding pad; and a second connection terminal on a second surface opposite to the first surface of the package substrate, the second connection terminal being connected to the plurality of conductive patterns, wherein the semiconductor chip is closer to a second edge of the package substrate opposite to a first edge of the package substrate, wherein conductive patterns disposed at an uppermost portion among the plurality of conductive patterns include a first conductive pattern overlapping a first side surface of the semiconductor chip in a vertical direction, a second conductive pattern overlapping a second side surface of the semiconductor chip in a vertical direction, and a third conductive pattern between the first side surface and the second side surface of the semiconductor chip, the third conductive pattern being connected to the bonding pad, wherein a thickness of a wiring portion of the first conductive pattern is greater than a thickness of a wiring portion of the second conductive pattern and a thickness of a wiring portion of the third conductive pattern, wherein the thickness of the wiring portion of the second conductive pattern and the thickness of the wiring portion of the third conductive pattern are substantially the same, and wherein the first conductive pattern includes a first groove recessed toward a bottom surface of the package substrate.

According to the embodiments, a semiconductor chip mounted on a package substrate may be biased and disposed adjacent to one edge or the other edge of the package substrate. Simultaneously, by forming a thickness of a conductive pattern of the package substrate overlapping a side surface of the semiconductor chip away from the one edge or the other edge of the package substrate to be thicker than that of another conductive pattern, the conductive pattern of the package substrate may be prevented from being damaged.

### BRIEF DESCRIPTION OF THE DRAWINGS

FIG. 1 is a plan view of a semiconductor package according to an embodiment.

FIG. 2 is a cross-sectional view cut along a line I-I′ of FIG. 1.

FIG. 3 is a partial enlarged view of a region P1 of FIG. 2.

FIG. 4 is a partial enlarged view of a region P2 of FIG. 2.

FIGS. 5 to 9 are partial enlarged views showing regions P3 to P7 corresponding to the region P1 of FIG. 2.

FIGS. 10, 13, 14, and 17 are cross-sectional views cut along the line I-I′ of FIG. 1 according to some embodiments.

FIG. 11 is a partial enlarged view of a region P8 of FIG. 10.

FIG. 12 is a partial enlarged view of a region P9 of FIG. 10.

FIG. 15 is a partial enlarged view of a region P10 of FIG. 14.

FIG. 16 is a partial enlarged view of a region P11 of FIG. 14.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thickness of layers, films, panels, regions, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

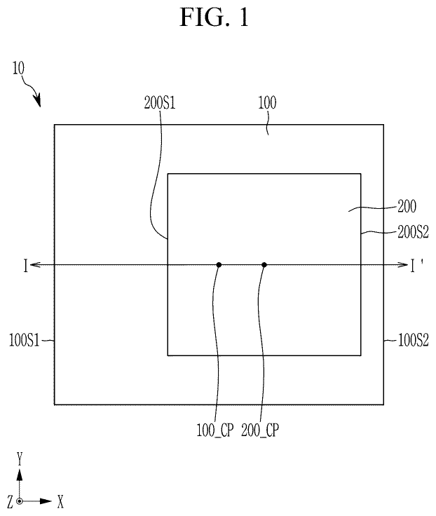

Hereinafter, a semiconductor package according to an embodiment will be described with reference to FIGS. 1 to 4.

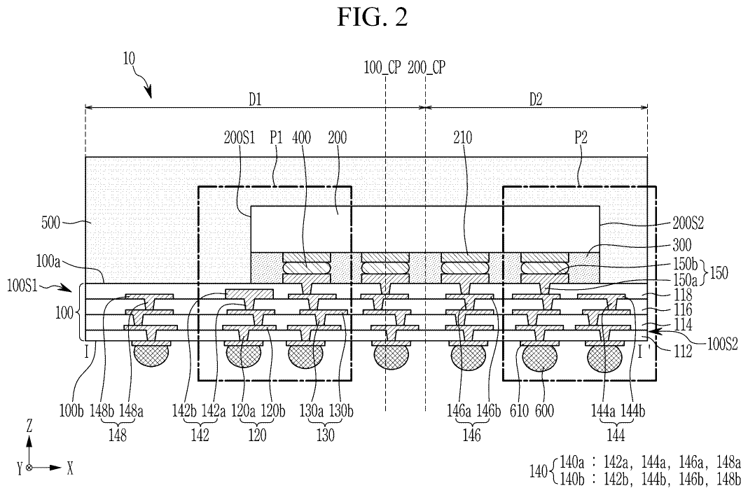

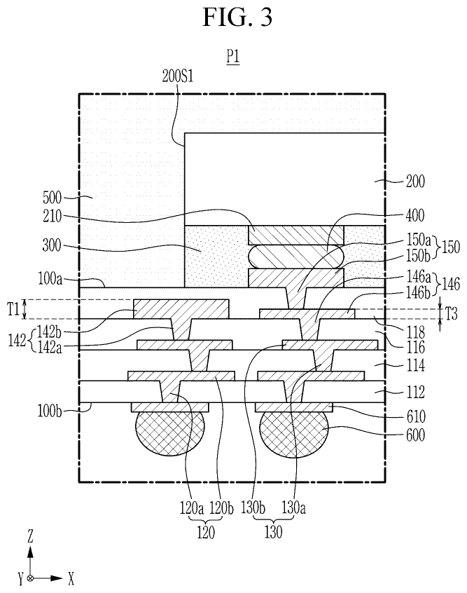

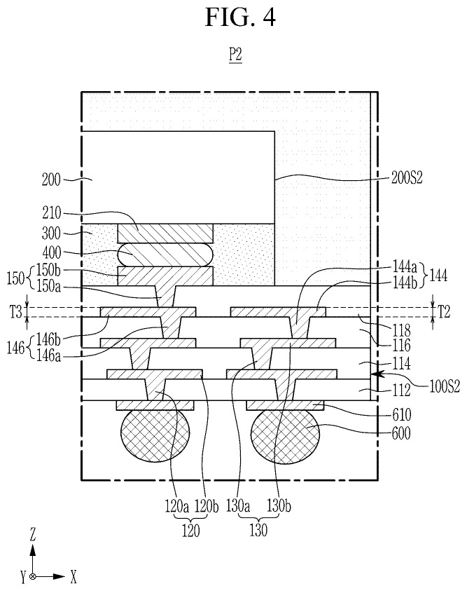

FIG. 1 is a plan view of a semiconductor package according to an embodiment. FIG. 2 is a cross-sectional view cut along a line I-I′ of FIG. 1. FIG. 3 is a partial enlarged view of a region P1 of FIG. 2. FIG. 4 is a partial enlarged view of a region P2 of FIG. 2.

Referring to FIGS. 1 to 4, the semiconductor package 10 according to the embodiment may include a package substrate 100, a semiconductor chip 200, an underfill member 300, a connection terminal 400, a molding member 500, and an external connection terminal 600.

In the present embodiment, the package substrate 100 may be a redistribution substrate. However, the present disclosure is not limited thereto, and in some embodiments, the package substrate 100 may be a printed circuit board (PCB), a ceramic substrate, a substrate for a wafer level package (WLP), or a substrate for a package level package (PLP).

The package substrate 100 may include a first surface 100a and a second surface 100b opposite to each other. A direction parallel to the first surface 100a of the package substrate 100 may be defined as a first direction X, a direction parallel to the first surface 100a of the package substrate 100 and perpendicular to the first direction X may be defined as a second direction Y, and a direction perpendicular to the first surface 100a of the package substrate 100 may be defined as a third direction Z (e.g., a vertical direction).

The package substrate 100 may include a plurality of insulating layers 112, 114, 116, and 118 and a plurality of conductive pattern layers 120, 130, and 140 disposed within the plurality of insulating layers 112, 114, 116, and 118.

The package substrate 100 may include a first insulating layer 112, a second insulating layer 114, a third insulating layer 116, and a fourth insulating layer 118 that are sequentially stacked. At least one of the first to fourth insulating layers 112, 114, 116, and 118 may have a different thickness from that of the other insulating layers. For example, the thickness of the first insulating layer 112 may be thinner than the thicknesses of the second to fourth insulating layers 114, 116, and 118, and the thicknesses of the second to fourth insulating layers 114, 116, and 118 may be substantially the same. However, a thickness relationship between the first to fourth insulating layers 112, 114, 116, and 118 is not limited thereto, and may be variously changed. For example, the thickness of the first to fourth insulating layers 112, 114, 116, and 118 may be substantially the same.

Each of the first to fourth insulating layers 112, 114, 116, and 118 may include an insulating material. For example, each of the first to fourth insulating layers 112, 114, 116, and 118 may include any one of silicon oxide, silicon nitride, silicon oxynitride, or a combination thereof. As another example, each of the first to fourth insulating layers 112, 114, 116, and 118 may include any one of photosensitivity polyimide, polybenzooxazole, a phenol-based polymer, a benzocyclobutene-based polymer, or a combination thereof. However, a material included in each of the first to fourth insulating layers 112, 114, 116, and 118 is not limited thereto, and may be variously changed.

In FIG. 2, the package substrate 100 is shown as including four insulating layers, but the number of insulating layers included in the package substrate 100 is not limited thereto, and may be variously changed. For example, some of the first to fourth insulating layers 112, 114, 116, and 118 may be omitted, or one or more insulating layers may be included in addition to the first to fourth insulating layers 112, 114, 116, and 118. As another example, the insulating layer included in the package substrate 100 may be formed of one insulating layer.

The package substrate 100 may include a plurality of lower conductive pattern layers 120, a plurality of middle conductive patterns 130, and a plurality of upper conductive pattern layers 140 that are disposed within the first to fourth insulating layers 112, 114, 116, and 118.

Each of the plurality of lower conductive pattern layers 120 may be formed by a damascene process. Each of the plurality of lower conductive pattern layers 120 may include a lower via portion 120a and a lower wiring portion 120b that are integrally formed with each other. There may be no boundary surface between the lower via portion 120a and the lower wiring portion 120b. The lower wiring portion 120b may be confined between two horizontal planes. The first horizontal plane may coincide with an upper surface of the first insulating layer 112 and the second horizontal plane may be between the upper surface of the first insulating layer 112 and an upper surface of the second insulating layer 114. The lower wiring portion 120b may be the portion of the lower conductive pattern layer 120 that has a width greater than its height.

A width of the lower wiring portion 120b along the first direction X may be greater than a width of the lower via portion 120a along the first direction X, and a thickness of the lower wiring portion 120b along the third direction Z may be less than a thickness of the lower via portion 120a along the third direction Z. That is, the lower conductive pattern layer 120 including the lower via portion 120a and the lower wiring portion 120b may have a T-shape in a cross-section. However, a relationship between the lower via portion 120a and the lower wiring portion 120b and a cross-sectional shape of the lower conductive pattern layer 120 are not limited thereto, and may be variously changed. For example, the lower via portion 120a and the lower wiring portion 120b may be configured as a separate configuration, and there may be a boundary surface between the lower via portion 120a and the lower wiring portion 120b.

The lower via portion 120a may penetrate the first insulating layer 112 to protrude from the lower wiring portion 120b toward the second surface 100b of the package substrate 100.

The lower wiring portion 120b may be disposed on an upper surface of the first insulating layer 112, and may be connected to the lower via portion 120a disposed within the first insulating layer 112. That is, the wiring portion 120b may be disposed on the upper portion surface of the first insulating layer 112. The lower wiring portion 120b may be entirely covered by the second insulating layer 114.

The lower wiring portion 120b may extend in a direction parallel to the upper surface of the first insulating layer 112, and may form a pad connected to the middle conductive pattern layer 130, or may form a redistribution line within the package substrate 100.

Each of the plurality of middle conductive pattern layers 130 may be formed by a damascene process. That is, each of the plurality of middle conductive pattern layers 130 may include a middle via portion 130a and a middle wiring portion 130b that are integrally formed with each other. There may be no boundary surface between the middle via portion 130a and the middle wiring portion 130b. The middle wiring portion 130b may be confined between two horizontal planes. The first horizontal plane may coincide with an upper surface of the second insulating layer 114 and the second horizontal plane may be between the upper surface of the second insulating layer 114 and an upper surface of the third insulating layer 116. The middle wiring portion 130b may be the portion of the middle conductive pattern layer 130 that has a width greater than its height.

A width of the middle wiring portion 130b along the first direction X may be greater than a width of the middle via portion 130a along the first direction X, and a thickness of the middle wiring portion 130b along the third direction Z may be less than a thickness of the middle via portion 130a along the third direction Z. That is, the middle conductive pattern layer 130 including the middle via portion 130a and the middle wiring portion 130b may have a T-shape in a cross-section. However, a relationship between the middle via portion 130a and the middle wiring portion 130b and a cross-sectional shape of the middle conductive pattern layer 130 are not limited thereto, and may be variously changed. For example, the middle via portion 130a and the middle wiring portion 130b may be configured as a separate configuration, and there may be a boundary surface between the middle via portion 130a and the middle wiring portion 130b.

The middle via portion 130a may penetrate the second insulating layer 114 to protrude from the middle wiring portion 130b toward the upper surface of the first insulating layer 112. The middle via portion 130a may be disposed within the second insulating layer 114, and may be connected to the lower wiring portion 120b of the lower conductive pattern layer 120 disposed on the upper surface of the first insulating layer 112.

The middle wiring portion 130b may be disposed on an upper surface of the second insulating layer 114, and may be connected to the middle via portion 130a disposed within the second insulating layer 114. That is, the middle wiring portion 130b may be disposed on the upper surface of the second insulating layer 114. The middle wiring portion 130b may be entirely covered by the third insulating layer 116.

The middle wiring portion 130b may extend in a direction parallel to the upper surface of the second insulating layer 114, and may form a pad connected to an upper conductive pattern layer 140, or may form a redistribution line within the package substrate 100.

Each of the plurality of upper conductive pattern layers 140 may be formed by a damascene process. Each of the plurality of upper conductive pattern layers 140 may include an upper via portion 140a and an upper wiring portion 140b that are integrally formed with each other. There may be no boundary surface between the upper via portion 140a and the upper wiring portion 140b. The upper wiring portion 140b may be confined between two horizontal planes. The first horizontal plane may coincide with an upper surface of the third insulating layer 116 and the second horizontal plane may be between the upper surface of the third insulating layer 116 and an upper surface of the fourth insulating layer 118. The upper wiring portion 140b may be the portion of the upper conductive pattern layer 140 that has a width greater than its height.

A width of the upper wiring portion 140b along the first direction X may be greater than a width of the upper via portion 140a along the first direction X, and a thickness of the upper wiring portion 140b along the third direction Z may be less than a thickness of the upper via portion 140a along the third direction Z. That is, the upper conductive pattern layer 140 including the upper via portion 140a and the upper wiring portion 140b may have a T-shape in a cross-section. However, a relationship between the upper via portion 140a and the upper wiring portion 140b and a cross-sectional shape of the upper conductive pattern layer 140 are not limited thereto, and may be variously changed. For example, the upper via portion 140a and the upper wiring portion 140b may be configured as a separate configuration, and there may be a boundary surface between the upper via portion 140a and the upper wiring portion 140b.

The upper via portion 140a may penetrate the third insulating layer 116 to protrude from the upper wiring portion 140b toward the upper surface of the second insulating layer 114.

The upper wiring portion 140b may be disposed on an upper surface of the third insulating layer 116, and may be connected to the upper via portion 140a disposed within the third insulating layer 116. That is, the upper wiring portion 140b may be disposed on the upper surface of the third insulating layer 116. The upper wiring portion 140b may be entirely covered by the fourth insulating layer 118.

In an embodiment, the upper conductive pattern layer 140 disposed at an uppermost portion of the package substrate 100 among the plurality of conductive pattern layers 120, 130, and 140 may include a first upper conductive pattern 142, a second upper conductive pattern 144, a third upper conductive pattern 146, and a fourth upper conductive pattern 148.

Each of the first to fourth upper conductive patterns 142, 144, 146, and 148 may include first to fourth upper via portions 142a, 144a, 146a, and 148a and first to fourth upper wiring portions 142b, 144b, 146b, and 148b. Descriptions of the first to fourth upper via portions 142a, 144a, 146a, and 148a and the first to fourth upper wiring portions 142b, 144b, 146b, and 148b are substantially the same as those of the upper via portion 140a and the upper wiring portion 140b described above, so that they are omitted.

The first upper conductive pattern 142, the second upper conductive pattern 144, the third upper conductive pattern 146, and the fourth upper conductive pattern 148 will be described later along with a disposition relationship between the first upper conductive pattern 142, the second upper conductive pattern 144, the third upper conductive pattern 146, and the fourth upper conductive pattern 148 and the semiconductor chip 200.

The lower conductive pattern layer 120, the middle conductive pattern layer 130, and the upper conductive pattern layer 140 may include a conductive material. For example, the lower conductive pattern layer 120, the middle conductive pattern layer 130, and the upper conductive pattern layer 140 may include copper (Cu). However, the conductive material included in the lower conductive pattern layer 120, the middle conductive pattern layer 130, and the upper conductive pattern layer 140 is not limited thereto, and may be variously changed.

In FIG. 2, the package substrate 100 is shown as including three conductive patterns, but the number of conductive patterns included in the package substrate 100 is not limited thereto, and may be variously changed. For example, one or more of the lower conductive pattern layer 120, the middle conductive pattern layer 130, and the upper conductive pattern layer 140 may be omitted, or one or more conductive patterns may be further included in addition to the lower conductive pattern layer 120, the middle conductive pattern layer 130, and the upper conductive pattern layer 140.

Although not shown in FIGS. 2 to 4, in some embodiments, a seed pattern that is disposed between the lower conductive pattern layer 120 and the first insulating layer 112, between the middle conductive pattern layer 130 and the second insulating layer 114, and between the upper conductive pattern layer 140 and the third insulating layer 116 and that includes a conductive material such as titanium (Ti) and/or tantalum (Ta) may be further included. For example, the seed pattern may cover both side surfaces of the lower via portion 120a and a lower surface of the lower wiring portion 120b.

Because a description of a disposition relationship between the lower conductive pattern layer 120 and the seed pattern is substantially and equally applied to a disposition relationship between the middle conductive pattern layer 130 and the upper conductive pattern layer 140 and the seed pattern, a description thereof is omitted.

The semiconductor package 10 according to the embodiment may further include a plurality of bonding pads 150 disposed on the upper conductive pattern layer 140. The plurality of bonding pads 150 may be connected to some of the plurality of upper conductive pattern layers 140.

Each of the plurality of bonding pads 150 may be formed by a damascene process. Each of the plurality of bonding pads 150 may include a bonding pad via portion 150a and a bonding pad portion 150b that are integrally formed with each other. There may be no boundary surface between the bonding pad via portion 150a and the bonding pad portion 150b.

A width of the bonding pad portion 150b along the first direction X may be greater than a width of the bonding pad via portion 150a along the first direction X, and a thickness of the bonding pad portion 150b along the third direction Z may be greater than a thickness of the bonding pad via portion 150a along the third direction Z. That is, the bonding pad 150 including the bonding pad via portion 150a and the bonding pad portion 150b may have a T-shape in a cross-section. However, a relationship between the bonding pad via portion 150a and the bonding pad portion 150b and a cross-sectional shape of the bonding pad 150 are not limited thereto, and may be variously changed. For example, the bonding pad via portion 150a and the bonding pad portion 150b may be configured as a separate configuration, and there may be a boundary surface between the bonding pad via portion 150a and the bonding pad portion 150b. As another example, the thickness of the bonding pad portion 150b along the third direction Z may be thinner than the thickness of the bonding pad via portion 150a along the third direction Z.

The bonding pad via portion 150a may penetrate the fourth insulating layer 118, may protrude from the bonding pad portion 150b toward the upper surface of the third insulating layer 116, and may be connected to a portion of the upper wiring portion 140b of the upper conductive pattern layer 140.

The bonding pad portion 150b may be disposed on an upper surface of the fourth insulating layer 118, and may be connected to the bonding pad via portion 150a disposed within the fourth insulating layer 118. That is, the bonding pad portion 150b may be disposed on the first surface 100a of the package substrate 100.

The bonding pad 150 may include a conductive material. For example, the bonding pad 150 may include copper (Cu). However, the conductive material included in the bonding pad 150 is not limited thereto, and may be variously changed.

The semiconductor chip 200 may be mounted above the package substrate 100. The semiconductor chip 200 may include any of a memory circuit, a logic circuit, or a combination thereof.

The semiconductor chip 200 may include a plurality of chip pads 210. The semiconductor chip 200 may be disposed on the first surface 100a of the package substrate 100. That is, the semiconductor chip 200 may be mounted above the package substrate 100 so that the plurality of chip pads 210 disposed on one surface of the semiconductor chip 200 face the first surface 100a of the package substrate 100.

Accordingly, the chip pads 210 of the semiconductor chip 200 may be disposed to correspond to the plurality of bonding pads 150 disposed on the first surface 100a of the package substrate 100.

The chip pad 210 may include a conductive material. For example, the chip pad 210 may include aluminum (Al). However, the conductive material included in the chip pad 210 is not limited thereto, and may be variously changed.

In an embodiment, the semiconductor chip 200 may be mounted above the first surface 100a of the package substrate 100 so that it is closer to any one of a first edge 100S1 and a second edge 100S2 of the package substrate 100 opposite to each other. That is, a central axis 200_CP (see, e.g., FIG. 2) of the semiconductor chip 200 mounted above the package substrate 100 and a central axis 100_CP of the package substrate 100 may be misaligned. In other words, because the semiconductor chip 200 is disposed closer to the first edge 100S1 or the second edge 100S2 of the package substrate 100 rather than a central portion of the package substrate 100, the semiconductor chip 200 may be mounted biased toward one side or the other side of the package substrate 100.

For example, the semiconductor chip 200 may be mounted above the package substrate 100 so that it is closer to the second edge 100S2 of the package substrate 100 as shown, e.g., in FIG. 2. That is, because the central axis 200_CP of the semiconductor chip 200 is disposed to be spaced apart from the central axis 100_CP of the package substrate 100 along the first direction X, the central axis 200_CP of the semiconductor chip 200 may be disposed closer to the second edge 100S2 of the package substrate 100 than the central axis 100_CP of the package substrate 100 is. In other words, a distance between a first side surface 200S1 of the semiconductor chip 200 disposed on the same side surface as that of the first edge 100S1 of the package substrate 100 and the central axis 100_CP of the package substrate 100 may be shorter than a distance between a second side surface 200S2 of the semiconductor chip 200 disposed on the same side surface as that of the second edge 100S2 of the package substrate 100 and the central axis 100_CP of the package substrate 100.

Hereinafter, a description will be made on an assumption that the semiconductor chip 200 is disposed closer to the second edge 100S2 of the package substrate 100.

In an embodiment, a first length along the first direction X between the first edge 100S1 of the package substrate 100 and the central axis 200_CP of the semiconductor chip 200 may be D1, a second length along the first direction X between the second edge 100S2 of the package substrate 100 and the central axis 200_CP of the semiconductor chip 200 may be D2, and the first length D1 may be longer than the second length D2. For example, a ratio between the first length D1 and the second length D2 may be about 6:4 to 7:3. However, the ratio between first length D1 and second length D2 is not limited to the above-described numerical range, and may be variously changed.

In an embodiment, the first upper conductive pattern 142 of the upper conductive pattern layer 140 disposed at an uppermost portion of the package substrate 100 among the plurality of conductive pattern layers 120, 130, and 140 may overlap the first side surface 200S1 of the semiconductor chip 200 in the third direction Z that is a vertical direction, and the second upper conductive pattern 144 may overlap the second side surface 200S2 of the semiconductor chip 200 in the third direction Z that is the vertical direction.

Accordingly, a distance between the first upper conductive pattern 142 and the first edge 100S1 of the package substrate 100 may be longer than a distance between the second upper conductive pattern 144 and the second edge 100S2 of the package substrate 100.

Specifically, a first upper wiring portion 142b of the first upper conductive pattern 142 may extend in the first direction X, a portion of the first upper wiring portion 142b may be disposed outside the first side surface 200S1 of the semiconductor chip 200 when viewed in plan view, and the remaining portion of the first upper wiring portion 142b may be disposed inside the first side surface 200S1 of the semiconductor chip 200 when viewed in plan view. That is, the portion of the first upper wiring portion 142b may not overlap a portion of the semiconductor chip 200 in the third direction Z that is the vertical direction, and the remaining portion of the first upper wiring portion 142b may overlap the semiconductor chip 200 in the third direction Z that is the vertical direction.

A second upper wiring portion 144b of the second upper conductive pattern 144 may extend in the first direction X, a portion of the second upper wiring portion 144b may be disposed outside the second side surface 200S2 of the semiconductor chip 200 when viewed in plan view, and the remaining portion of the second upper wiring portion 144b may be disposed inside the second side surface 200S2 of the semiconductor chip 200 when viewed in plan view. In other words, the portion of the second upper wiring portion 144b may not overlap a portion of the semiconductor chip 200 in the third direction Z that is the vertical direction, and the remaining portion of the second upper wiring portion 144b may overlap the semiconductor chip 200 in the third direction Z that is the vertical direction.

Each of the first upper wiring portion 142b of the first upper conductive pattern 142 and the second upper wiring portion 144b of the second upper conductive pattern 144 may be connected to the middle conductive pattern layer 130 and the lower conductive pattern layer 120 through the first upper via portion 142a and the second upper via portion 144a, and may form a redistribution line within the package substrate 100.

In an embodiment, the upper conductive pattern 140 disposed at an uppermost portion of the package substrate 100 among the plurality of conductive pattern layers 120, 130, and 140 may include a plurality of third upper conductive patterns 146 disposed between the first and second side surfaces 200S1 and 200S2 of the semiconductor chip 200 when viewed in plan view. For example, the plurality of third upper conductive patterns 146 may be disposed beneath the semiconductor chip 200.

The third upper conductive patterns 146 may be disposed between the first side surface 200S1 and the second side surface 200S2 of the semiconductor chip 200, and may completely overlap the semiconductor chip 200 in the third direction Z that is the vertical direction. That is, because the first upper conductive pattern 142 is disposed at one side of the first direction X of the third upper conductive patterns 146 and the second upper conductive pattern 144 is disposed at the other side of the first direction X, the third upper conductive patterns 146 may be disposed between the first upper conductive pattern 142 and the second upper conductive pattern 144.

The bonding pad 150 described above may be disposed on the third upper conductive pattern 146. That is, the bonding pad portion 150b of the bonding pad 150 may be connected to a third upper wiring portion 146b of the third upper conductive pattern 146 through the bonding pad via portion 150a. That is, the third upper wiring portion 146b may form a pad connected to the bonding pads 150.

A plurality of connection terminals 400 may be disposed between the bonding pad 150 of the package substrate 100 and the chip pad 210 of the semiconductor chip 200. That is, the connection terminal 400 may be connected to the bonding pad 150 and the chip pad 210, so that the package substrate 100 and the semiconductor chip 200 are electrically connected to each other.

Here, the electrical connection may include both direct and indirect connection, and the electrical connection of the semiconductor chip 200 to the package substrate 100 may mean the electrical connection of the semiconductor chip 200 to at least one of the lower conductive pattern layer 120, the middle conductive pattern layer 130, and the upper conductive pattern layer 140 included in the package substrate 100.

For example, the connection terminal 400 may be at least one of a solder ball, a pillar, and a bump. However, a type of the connection terminal 400 is not limited thereto, and may be variously changed.

The connection terminal 400 may include a conductive material. For example, the connection terminal 400 may include any one of tin (Sn), silver (Ag), zinc (Zn), lead (Pb), and a combination thereof. However, the conductive material included in the connection terminal 400 is not limited thereto, and may be variously changed.

In an embodiment, the upper conductive pattern layer 140 disposed at an uppermost portion of the package substrate 100 among the plurality of conductive pattern layers 120, 130, and 140 may include a fourth upper conductive pattern 148 that does not overlap the semiconductor chip 200 in the third direction Z that is the vertical direction.

The fourth upper conductive pattern 148 may be disposed outside the first side surface 200S1 of the semiconductor chip 200 when viewed in plan view. That is, the fourth upper conductive pattern 148 may be disposed outside the first upper conductive pattern 142. Although FIGS. 2 to 4 show that the fourth upper conductive pattern 148 is disposed only outside the first side surface 200S1 of the semiconductor chip 200, the present disclosure is not limited thereto, and in some embodiments, the fourth upper conductive pattern 148 may be further disposed outside the second side surface 200S2 of the semiconductor chip 200.

A fourth upper wiring portion 148b of the fourth upper conductive pattern 148 may be connected to the middle conductive pattern layer 130 and the lower conductive pattern layer 120 through a fourth upper via portion 148a, and may form a redistribution line within the package substrate 100. Although not shown in the drawings, in some embodiments, the fourth upper conductive pattern 148 may form a pad connected to a conductive pillar connecting the conductive patterns disposed at an upper region of the semiconductor chip 200 to the lower conductive pattern 120 and the middle conductive pattern 130 included in the package substrate 100.

In FIGS. 2 to 4, the plurality of conductive pattern layers 120, 130, and 140 of the package substrate 100 and the semiconductor chip 200 are electrically connected to each other by the connection terminal 400, but a connection relationship between the package substrate 100 and the semiconductor chip 200 is not limited thereto, and may be variously changed. For example, the plurality of conductive pattern layers 120, 130, and 140 included in the package substrate 100 may be connected to the semiconductor chip 200 by wire bonding. As another example, the connection terminal 400 disposed between the package substrate 100 and the semiconductor chip 200 may be omitted, and the plurality of conductive pattern layers 120, 130, and 140 included in the package substrate 100 may be directly connected to the semiconductor chip 200.

The underfill member 300 may be disposed between the first surface 100a of the package substrate 100 and the semiconductor chip 200. The underfill member 300 may fill a gap region remaining after the bonding pad 150, the connection terminal 400, and the chip pad 210 are formed between the first surface 100a of the package substrate 100 and the semiconductor chip 200.

The underfill member 300 may cover the first surface 100a of the package substrate 100, one surface of the semiconductor chip 200 facing the first surface 100a of the package substrate 100, a side surface of the chip pad 210, a side surface of the connection terminal 400, and a side surface of the bonding pad 150.

The underfill member 300 may include an insulating material. For example, the underfill member 300 may include an epoxy-based polymer. However, a material included in the underfill member 300 is not limited thereto, and may be variously changed.

In FIGS. 2 to 4, both side surfaces of the underfill member 300 are shown to be aligned at substantially the same boundary as those of the first side surface 200S1 and the second side surface 200S2 of the semiconductor chip 200, but the present disclosure is not limited thereto. For example, both side surfaces of the underfill member 300 may be disposed by extending further to one side and the other side of the first direction X than the first side surface 200S1 and the second side surface 200S2 of the semiconductor chip 200, respectively.

Additionally, in some embodiments, the underfill member 300 disposed between the package substrate 100 and the semiconductor chip 200 may be omitted.

The molding member 500 may be disposed on the first surface 100a of the package substrate 100. The molding member 500 may cover a portion of the first surface 100a of the package substrate 100 and a side surface of the underfill member 300. The molding member 500 may entirely cover the semiconductor chip 200.

As described above, because the semiconductor chip 200 is disposed closer to the second edge 100S2 of the package substrate 100 than to the first edge 100S1 of the package substrate 100, a width of the molding member 500 along the first direction X disposed between the first edge 100S1 of the package substrate 100 and the first side surface 200S1 of the semiconductor chip 200 may be greater than a width of the molding member 500 along the first direction X disposed between the second edge 100S2 of the package substrate 100 and the second side surface 200S2 of the semiconductor chip 200.

In some embodiments, if the above-described underfill member 300 is omitted, the molding member 500 may fill a gap region remaining after the bonding pad 150, the connection terminal 400, and the chip pad 210 are formed between the first surface 100a of the package substrate 100 and the semiconductor chip 200.

The molding member 500 may include an insulating material. For example, the molding member 500 may include an insulating polymer such as an epoxy-based molding compound (EMC). However, a material included in the molding member 500 is not limited thereto, and may be variously changed.

As shown in FIG. 3 and FIG. 4, the first upper wiring portion 142b disposed at an uppermost portion of the package substrate 100 may have a first thickness T1, the second upper wiring portion 144b may have a second thickness T2, and the third upper wiring portion 146b may have a third thickness T3.

In an embodiment, the first thickness T1 may be thicker than the second thickness T2 and the third thickness T3, and the second thickness T2 and the third thickness T3 may be substantially the same. However, a relationship between the first thickness T1, the second thickness T2, and the third thickness T3 is not limited thereto, and may be variously changed.

Additionally, in some embodiments, a thickness of the fourth upper wiring portion 148b of the fourth upper conductive pattern 148 may be thinner than the first thickness T1, and may be substantially the same as the second thickness T2 and the third thickness T3. However, a relationship between the thickness of the fourth upper wiring portion 148b of the fourth upper conductive pattern 148 and the first thickness T1, the second thickness T2, and the third thickness T3 is not limited thereto, and may be variously changed. For example, the thickness of the fourth upper wiring portion 148b may be substantially the same as the first thickness T1, and may be thicker than the second thickness T2 and the third thickness T3.

In an embodiment, the first thickness T1 may be about 1.3 times or more the second thickness T2 and the third thickness T3. For example, the first thickness T1 may be about 1.3 to 2.5 times the second thickness T2 and the third thickness T3. However, this is an example, and a numerical relationship between the first thickness T1, the second thickness T2, and the third thickness T3 is not limited thereto, and may be variously changed.

Although FIGS. 2 to 4 show that a thickness of the first upper wiring portion 142b of the first upper conductive pattern 142 extending in the first direction X is constant, a shape of the first upper wiring portion 142b is not limited thereto, and may be variously changed. For example, in some embodiments, the first upper wiring portion 142b extending in the first direction X may include portions having different thicknesses. That is, a thickness of the first upper wiring portion 142b disposed outside the first side surface 200S1 of the semiconductor chip 200 may be thicker than a thickness of the first upper wiring portion 142b disposed inside the first side surface 200S1 of the semiconductor chip 200.

For comparison between the semiconductor package 10 according to the embodiment and a semiconductor package according to a reference example, the semiconductor package according to the reference example may be considered. In the semiconductor package according to the reference example, a semiconductor chip may be mounted at a central portion of a package substrate.

Because the semiconductor package according to the reference example repeatedly contracts and expands due to an external temperature change or a temperature change occurring in a process step, stress may occur at an outer portion of the semiconductor chip that is positioned at both side surfaces of the semiconductor chip in direct contact with a molding member.

Because a thermal expansion coefficient of the molding member including an insulating material is relatively greater than a thermal expansion coefficient of the semiconductor chip including a conductive material, a difference between the expansion and the contraction may occur due to the temperature change, so that a size of a stress occurring at a region adjacent to a boundary surface between the molding member and the semiconductor chip may be greater than a size of a stress occurring at another region.

In addition, because an insulating layer of the package substrate that is in direct contact with the molding member and is disposed adjacent to both side surfaces of the semiconductor chip also includes an insulating material unlike the semiconductor chip that includes the conductive material, a relatively large difference between expansion and contraction may occur at the insulating layer compared with the semiconductor chip, so that a size of a stress generated at a region of the insulating layer of the package substrate that overlaps the both side surfaces of the semiconductor chip may be larger than a size of a stress generated at another region.

Accordingly, a crack may occur at an uppermost conductive pattern buried within the insulating layer of the package substrate that is in direct contact with the molding member covering both side surfaces of the semiconductor chip and is disposed adjacent to both side surfaces of the semiconductor chip.

Because the semiconductor chip 200 according to an embodiment is biased and mounted at the other side of the package substrate 100 in the semiconductor package 10, a distance between the first side surface 200S1 of the semiconductor chip 200 and the first edge 100S1 of the package substrate 100 may increase compared with a case where the semiconductor chip 200 is mounted at a central portion of the package substrate 100, and a distance between the second side surface 200S2 of the semiconductor chip 200 and the second edge 100S2 of the package substrate 100 may decrease compared with the case where the semiconductor chip 200 is mounted at the central portion of the package substrate 100.

Accordingly, because lengths of the insulating layers 112, 114, 116, and 118 of the package substrate 100 along the first direction X disposed outside the first side surface 200S1 of the semiconductor chip 200 and a length of the molding member 500 along the first direction X increase, a stress generated at a region adjacent to the first side surface 200S1 of the semiconductor chip 200 may be greater than that of the case where the semiconductor chip 200 is mounted at the central portion of the package substrate 100.

On the other hand, because lengths of the insulating layers 112, 114, 116, and 118 of the package substrate 100 along the first direction X disposed outside the second side surface 200S2 of the semiconductor chip 200 and the length of the molding member 500 along the first direction X decrease, a stress generated at a region adjacent to the second side surface 200S2 of the semiconductor chip 200 may be reduced compared with the case where the semiconductor chip 200 is mounted at the central portion of the package substrate 100.

Because a thickness of the first upper wiring portion 142b that overlaps the first side surface 200S1 of the semiconductor chip 200 in a vertical direction and is disposed at an uppermost portion of the package substrate 100 is formed relatively thicker than thicknesses of the second to fourth upper wiring portions 144b, 146b, and 148b disposed at the uppermost portion of the package substrate 100, durability against an increased stress at a region adjacent to the first side surface 200S1 of the semiconductor chip 200 may be improved.

In other words, the semiconductor chip 200 may be biased and mounted toward the second edge 100S2 of the package substrate 100. Thus, even if a stress generated at a region adjacent to the first side surface 200S1 of the semiconductor chip 200 increases, the thickness of the first upper wiring portion 142b that overlaps the first side surface 200S1 of the semiconductor chip 200 in the vertical direction may be formed relatively thicker than the thicknesses of the second to fourth upper wiring portions 144b, 146b, and 148b, so that it is possible to suppress occurrence of a crack in the first upper conductive pattern 142.

The semiconductor package 10 according to the embodiment may further include a plurality of external connection terminal pads 610 disposed on the second surface 100b of the package substrate 100.

A plurality of external connection terminals 600 may be disposed on the second surface 100b of the package substrate 100. The external connection terminal pad 610 may be disposed between the package substrate 100 and the external connection terminal 600 on the second surface 100b of the package substrate 100.

Some of the plurality of external connection terminals 600 may completely overlap the semiconductor chip 200 in the third direction Z that is the vertical direction. Some of the plurality of external connection terminals 600 may overlap the first side surface 200S1 or the second side surface 200S2 of the semiconductor chip 200 in the third direction Z that is the vertical direction. Some of the plurality of external connection terminals 600 may not overlap the semiconductor chip 200 in the third direction Z that is the vertical direction.

The external connection terminal 600 may be connected to the semiconductor chip 200 through the external connection terminal pad 610 and the conductive pattern layers 120, 130, and 140 of the package substrate 100.

For example, the external connection terminal 600 may be at least one of a solder ball, a pillar, and a bump. However, a type of the external connection terminal 600 is not limited thereto, and may be variously changed.

The external connection terminal 600 may include a conductive material. For example, the external connection terminal 600 may include any one of tin (Sn), silver (Ag), zinc (Zn), lead (Pb), and a combination thereof. However, the conductive material included in the external connection terminal 600 is not limited thereto, and may be variously changed.

The above description assumes that the semiconductor chip 200 is disposed closer to the second edge 100S2 of the package substrate 100. However, if the semiconductor chip 200 is disposed closer to the first edge 100S1 of the package substrate 100, a thickness relationship between the first to fourth upper wiring portions 142b, 144b, 146b, and 148b may vary. For example, in an embodiment in which the semiconductor chip 200 is disposed closer to the first edge 100S1 of the package substrate 100, the first side surface 200S1 of the semiconductor chip 200 may overlap the fourth upper wiring portion 148b in the third direction Z that is the vertical direction, and in an embodiment in which the second side surface 200S2 overlaps any one of third upper wiring portions 146b in the third direction Z that is the vertical direction, a thickness of the third upper wiring portion 146b overlapping the second side surface 200S2 of the semiconductor chip 200 may be greater than thicknesses of the first upper wiring portion 142b and the third upper wiring portion 146b disposed between the first side surface 200S1 and the second side surface 200S2 of the semiconductor chip 200 and a thickness of the second upper wiring portion 144b that does not overlap the semiconductor chip 200 in the third direction Z that is the vertical direction.

Thus, the above description may be substantially and equally applied to a case in which the semiconductor chip 200 is disposed closer to the first edge 100S1 of the package substrate 100.

According to the semiconductor package 10 according to the embodiment, because a thickness of the conductive pattern of the package substrate 100 overlapping an end portion (e.g., a side surface) of the semiconductor chip 200 that is biased and mounted at one side or the other side of the package substrate 100 and is disposed away from the one side or the other side of the package substrate 100 is formed relatively thicker than that of another conductive pattern, it is possible to suppress occurrence of a crack in the conductive pattern of the package substrate 100 overlapping both end portions of the semiconductor chip 200 compared with the case where the semiconductor chip 200 is mounted at the central portion of the package substrate 100.

In addition, because a conductive pattern is additionally formed only on the conductive pattern of the package substrate 100 overlapping one end portion (e.g., side surface) or the other end portion (e.g., side surface) of the semiconductor chip 200 to be relatively thicker, a production cost of the semiconductor package may be reduced, and a production process step of the semiconductor package may be simplified compared with a case in which a conductive pattern is additionally formed on the conductive pattern of the package substrate 100 overlapping both end portions (e.g., side surfaces) of the semiconductor chip 200 such that both conductive patterns are formed to be relatively thicker.

Accordingly, reliability and productivity of the semiconductor package according to the embodiment may be improved.

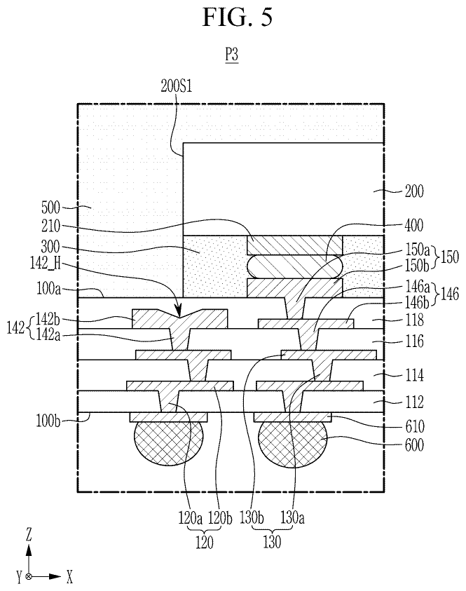

Hereinafter, the semiconductor package according to various embodiments will be described with reference to FIGS. 5 to 17. In the following embodiment, the same configuration described above will be referred to by the same reference numeral, and a redundant description will be omitted or simplified, and a difference will be mainly described.

FIGS. 5 to 9 are cross-sectional views showing the semiconductor package according to some embodiments. Specifically, FIGS. 5 to 9 show regions P3 to P7 corresponding to a region P1 of FIG. 2.

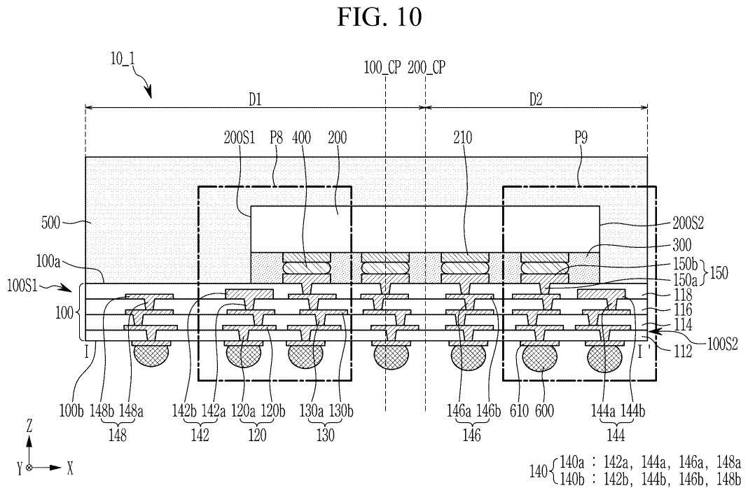

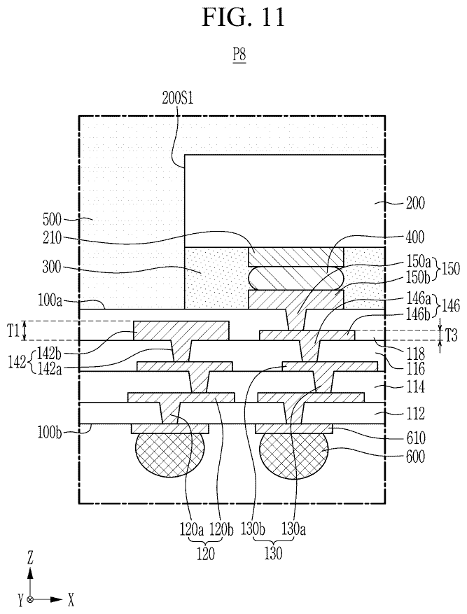

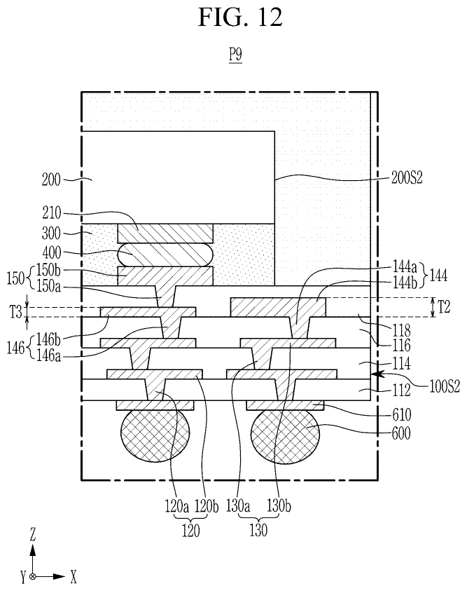

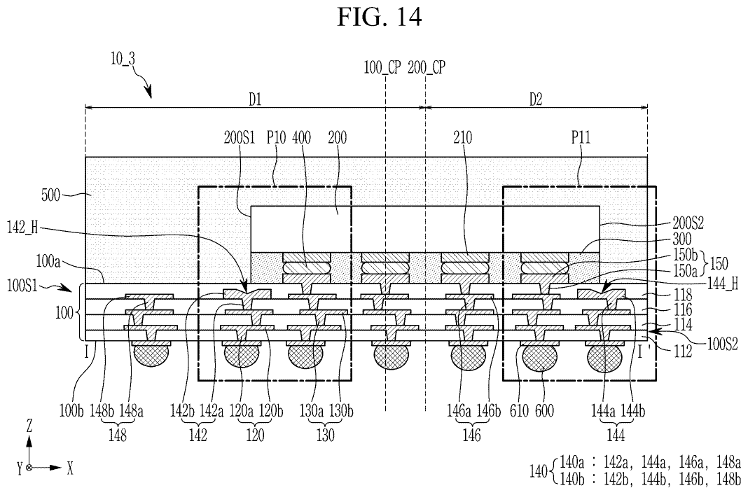

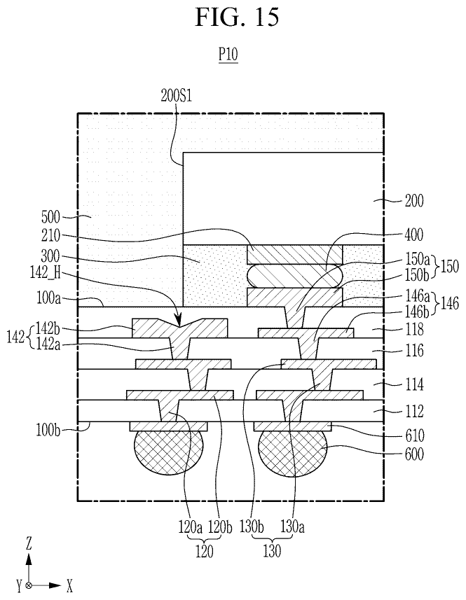

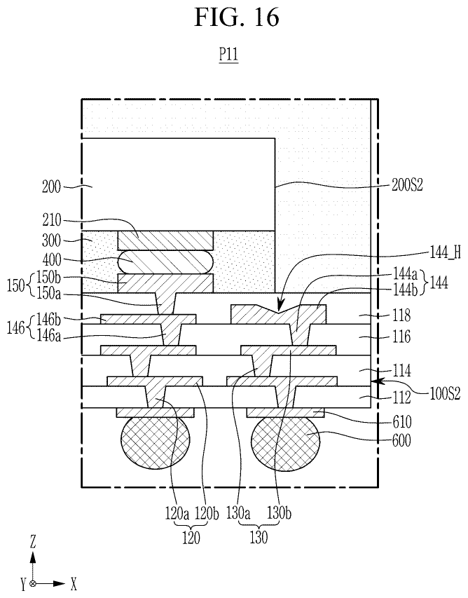

FIGS. 10, 13, 14, and 17 are cross-sectional views cut along the line I-I′ of FIG. 1 according to some embodiments. FIG. 11 is a partial enlarged view of a region P8 of FIG. 10. FIG. 12 is a partial enlarged view of a region P9 of FIG. 10. FIG. 15 is a partial enlarged view of a region P10 of FIG. 14. FIG. 16 is a partial enlarged view of a region P11 of FIG. 14.

According to the embodiments shown in FIGS. 5 to 7, unlike the embodiment shown in FIG. 3, there is a difference in that the first upper conductive pattern 142 further includes a first groove 142_H.

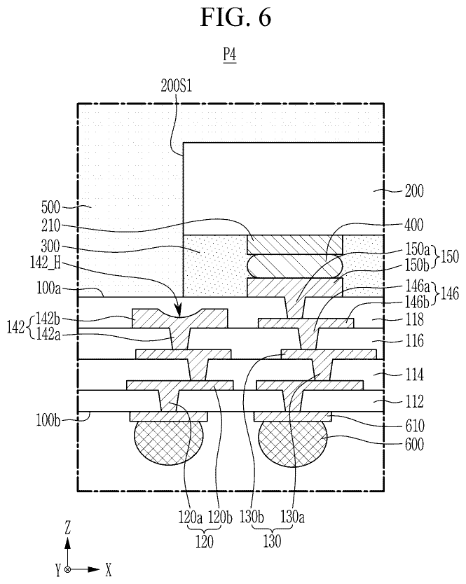

Specifically, referring to FIG. 5 and FIG. 6, the first upper conductive pattern 142 may include the first groove 142_H recessed from an upper surface of the first upper wiring portion 142b toward the first upper via portion 142a. That is, the first groove 142_H may have a recessed shape from the upper surface of the first upper wiring portion 142b toward the first upper via portion 142a on a cross-section. For example, the first groove 142_H may be recessed toward a bottom surface of the package substrate 100.

An inner surface of the first groove 142_H may include a straight line or a curved line. For example, as shown in FIG. 5, the first groove 142_H may have a V-shape in a cross-section. That is, the first groove 142_H may have an inverse triangle shape in a cross-section. That is, the inner surface of the first groove 142_H may have an inverted tapered inclined surface with respect to an upper portion surface of the third insulating layer 116.

In another example, as shown in FIG. 6, the first groove 142_H may have a U-shape in a cross-section. That is, the first groove 142_H may have a semicircular or semi ovular shape on a cross-section. For example, the first groove 142_H may have the shape of an arc. That is, the inner surface of the first groove 142_H may include a curved surface. However, the number of first grooves 142_H and a shape of the first groove 142_H are not limited thereto, and may be variously changed. For example, the first groove 142_H may have a polygonal shape on a cross-section. As another example, the first upper conductive pattern 142 may include a plurality of first grooves 142_H.

In the present embodiment, the first groove 142_H may be disposed approximately at a central portion of the first upper wiring portion 142b. At least a portion of the first groove 142_H may overlap the first side surface 200S1 of the semiconductor chip 200 in the third direction Z that is the vertical direction. That is, a portion of the first groove 142_H may be disposed outside the first side surface 200S1 of the semiconductor chip 200 when viewed in plan view, and the remaining portion of the first groove 142_H may be disposed inside the first side surface 200S1 of the semiconductor chip 200 when viewed in plan view. However, a position of the first groove 142_H is not limited thereto, and may be variously changed. For example, the first groove 142_H may be disposed closer to one side or the other side of the first direction X of the first upper wiring portion 142b.

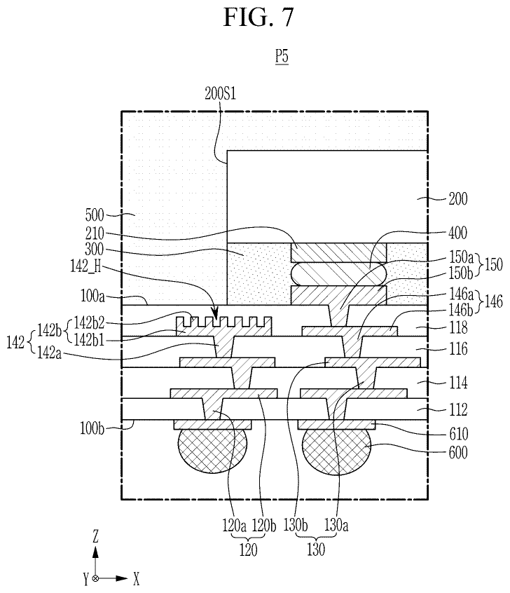

According to the embodiment shown in FIG. 7, unlike the embodiment shown in FIG. 5 and FIG. 6, there is a difference in that the first upper conductive pattern 142 includes the plurality of first grooves 142_H.

Referring to FIG. 7, the first upper wiring portion 142b of the first upper conductive pattern 142 may include the plurality of first grooves 142_H recessed from an upper surface thereof toward the upper surface of the third insulating layer 116.

Specifically, the first upper wiring portion 142b may include a base portion 142b1 and a plurality of protruding portions 142b2 disposed on the base portion 142b1. The plurality of protruding portions 142b2 may protrude from the base portion 142b1 toward the third direction Z that is the vertical direction, and the plurality of protruding portions 142b2 may be disposed spaced apart from each other on the base portion 142b1.

The base portion 142b1 may include a region where the protruding portion 142b2 is disposed and a region where the protruding portion 142b2 is not disposed, and the regions may be alternately disposed. Each of the plurality of first grooves 142_H may be defined by the protruding portions 142b2 adjacent to an upper surface of the base portion 142b1.

The first upper wiring portion 142b may have a surface uneven structure depending on presence or absence of the protruding portion 142b2. For example, the upper surface of the first upper wiring portion 142b may be uneven. That is, because the protruding portion 142b2 and the first groove 142_H of the first upper wiring portion 142b are alternately disposed along the first direction X, the upper surface of the first upper wiring portion 142b may have an uneven structure.

According to the present embodiment, a portion of the first groove 142_H may be disposed outside the first side surface 200S1 of the semiconductor chip 200 when viewed in plan view, and the remaining portion of the first groove 142_H may be disposed inside the first side surface 200S1 of the semiconductor chip 200 when viewed in plan view. That is, some of the plurality of first grooves 142_H included in the first upper wiring portion 142b may overlap the semiconductor chip 200 in the third direction Z that is the vertical direction, and the remaining portion of the plurality of first grooves 142_H may not overlap the semiconductor chip 200 in the third direction Z that is the vertical direction.

The semiconductor package according to FIGS. 5 to 7 may obtain substantially the same effect as that of the semiconductor package 10 according to the embodiment.

Additionally, according to the semiconductor package according to the embodiment shown in FIGS. 5 to 7, because the first groove 142_H is disposed at the first upper wiring portion 142b of the first upper conductive pattern 142 overlapping the first side surface 200S1 of the semiconductor chip 200, a crack may be suppressed from being propagated to another region of the first upper wiring portion 142b by the presence of the first groove 142_H even if the crack occurs at a portion of the first upper wiring portion 142b.

Accordingly, even if the crack occurs at a portion of the first upper conductive pattern 142, the crack may not affect the first upper wiring portion 142b performing a role of a redistribution line.

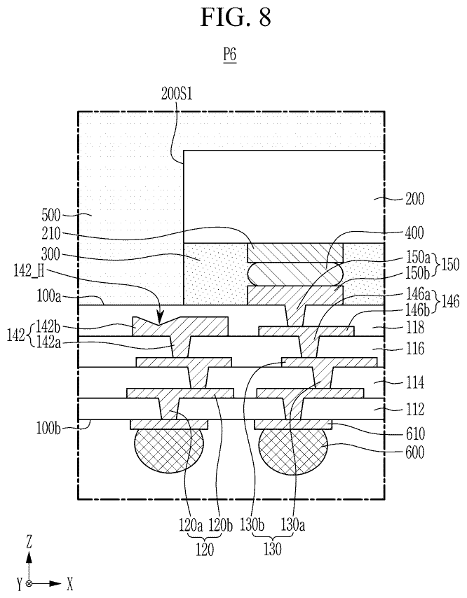

According to the embodiment shown in FIG. 8, unlike the embodiment shown in FIG. 5 and FIG. 6, there is a difference in that an overlapping relationship between the first groove 142_H of the first upper conductive pattern 142 and the semiconductor chip 200 is different.

Specifically, unlike the embodiment shown in FIG. 5 in which the first groove 142_H is disposed approximately at a central portion of the first upper wiring portion 142b, in the present embodiment, the first groove 142_H may be disposed closer to one side surface or the other side surface along the first direction X of the first upper wiring portion 142b.

The first groove 142_H of the first upper conductive pattern 142 may not overlap the semiconductor chip 200 in the third direction Z that is the vertical direction. That is, because the first groove 142_H is disposed outside the first side surface 200S1 of the semiconductor chip 200 when viewed in plan view, the first groove 142_H may not overlap the semiconductor chip 200 in the third direction Z that is the vertical direction. However, a position of the first groove 142_H is not limited thereto, and may be variously changed. For example, in some embodiments, a portion of the first groove 142_H may be disposed outside the first side surface 200S1 of the semiconductor chip 200, and the remaining portion of the first groove 142_H may be disposed inside the first side surface 200S1 of the semiconductor chip 200. An area of the first groove 142_H disposed outside the first side surface 200S1 of the semiconductor chip 200 may be larger than an area of the first groove 142_H disposed inside the first side surface 200S1 of the semiconductor chip 200. In other words, an area of the first groove 142_H that overlaps the semiconductor chip 200 in the third direction Z that is the vertical direction may be smaller than an area of the first groove 142_H that does not overlap the semiconductor chip 200 in the third direction Z that is the vertical direction.

Although FIG. 8 shows that the first groove 142_H has a V-shape in a cross-section, a shape of the first groove 142_H is not limited thereto, and may be variously changed. For example, like the embodiment shown in FIG. 6, the first groove 142_H according to the present embodiment may have a U-shape in cross section, and may not overlap the semiconductor chip 200 in the third direction Z that is the vertical direction.

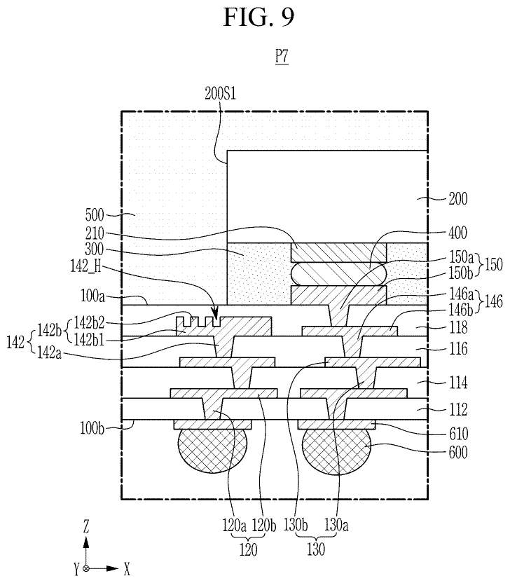

According to the embodiment shown in FIG. 9, unlike the embodiment shown in FIG. 7, there is a difference in that the plurality of first grooves 142_H have an uneven structure disposed at some regions of an upper surface of the first upper wiring portion 142b.

Specifically, unlike the embodiment shown in FIG. 7 in which the plurality of first grooves 142_H defined by the protruding portions 142b2 adjacent to an upper portion surface of the base portion 142b1 are disposed at an entire region of the upper surface of the first upper wiring portion 142b, in the present embodiment, the plurality of first grooves 142_H may be disposed only at a region adjacent to one side surface or the other side surface along the first direction X of the first upper wiring portion 142b.

Accordingly, in the present embodiment, the uneven structure may be disposed only at some regions of the upper surface of the first upper wiring portion 142b.

The plurality of first grooves 142_H of the first upper conductive pattern 142 may not overlap the semiconductor chip 200 in the third direction Z that is the vertical direction. In other words, because the plurality of first grooves 142_H are disposed outside the first side surface 200S1 of the semiconductor chip 200 when viewed in plan view, the plurality of first grooves 142_H may not overlap the semiconductor chip 200 in the third direction Z that is the vertical direction. In other words, the uneven structure disposed on the upper surface of the first upper wiring portion 142b may not overlap the semiconductor chip 200 in the third direction Z that is the vertical direction. However, positions of the plurality of first grooves 142_H are not limited thereto, and may be variously changed. For example, in some embodiments, a portion of the first groove 142_H may be disposed outside the first side surface 200S1 of the semiconductor chip 200, and the remaining portion of the first groove 142_H may be disposed inside the first side surface 200S1 of the semiconductor chip 200. The number of first grooves 142_H disposed outside the first side surface 200S1 of the semiconductor chip 200 may be greater than the number of first grooves 142_H disposed inside the first side surface 200S1 of the semiconductor chip 200. That is, the number of first grooves 142_H that overlap the semiconductor chip 200 in the third direction Z that is the vertical direction may be less than the number of first grooves 142_H that do not overlap the semiconductor chip 200 in the third direction Z that is the vertical direction.

The semiconductor package according to FIG. 8 and FIG. 9 may obtain substantially the same effect as that of the semiconductor package 10 according to FIGS. 5 to 7.

In addition, according to the semiconductor package according to the embodiment shown in FIG. 8 and FIG. 9, even if a crack occurs at a region of the first upper wiring portion 142b disposed outside the first side surface 200S1 of the semiconductor chip 200, the first groove 142_H of the first upper conductive pattern 142 disposed outside the first side surface 200S1 of the semiconductor chip 200 may suppress propagation of a crack to a region of the first upper wiring portion 142b disposed inside the first side surface 200S1 of the semiconductor chip 200.

In addition, because the first groove 142_H is formed only at the region of the first upper wiring portion 142b disposed outside the first side surface 200S1 of the semiconductor chip 200, a thickness of the region of the first upper wiring portion 142b disposed inside the first side surface 200S1 of the semiconductor chip 200 is relatively greater than a thickness of a region of the first upper wiring portion 142b in which the first groove 142_H is formed. Thus, durability of a region of the first upper wiring portion 142b disposed inside the first side surface 200S1 of the semiconductor chip 200 may be maintained.

According to the semiconductor package 10_1 according to the embodiment shown in FIGS. 10 to 12, unlike the embodiment shown in FIG. 3 and FIG. 4, there is a difference in that a thickness of the second upper wiring part 144b varies. The second upper wiring part 144b is of the second upper conductive pattern 144 overlapping the second side surface 200S2 of the semiconductor chip 200 in the third direction Z that is the vertical direction among the upper conductive pattern 140 disposed at an uppermost portion of the package substrate 100.

Specifically, as shown in FIGS. 10 to 12, the first upper wiring portion 142b disposed at an uppermost portion of the package substrate 100 may have a first thickness T1, the second upper wiring portion 144b may have a second thickness T2, and the third upper wiring portion 146b may have a third thickness T3.

In the present embodiment, the first thickness T1 and the second thickness T2 may be thicker than the third thickness T3, and the first thickness T1 and the second thickness T2 may be substantially the same. However, a relationship between the first thickness T1, the second thickness T2, and the third thickness T3 is not limited thereto, and may be variously changed. For example, the first thickness T1 may be thicker than the second thickness T2 and the third thickness T3, and the second thickness T2 may be thicker than the third thickness T3. That is, because a size of a stress generated at a region adjacent to the second side surface 200S2 of the semiconductor chip 200 is smaller than a size of a stress generated at a region adjacent to the first side surface 200S1 of the semiconductor chip 200, durability against the stress generated at the region adjacent to the second side surface 200S2 of the semiconductor chip 200 may be maintained even if a thickness of the second upper wiring portion 144b overlapping the second side surface 200S2 of the semiconductor chip 200 is formed to be thinner than that of the first upper wiring portion 142b overlapping the first side surface 200S1 of the semiconductor chip 200.

Accordingly, the thickness T1 of the first upper wiring portion 142b overlapping the first side surface 200S1 of the semiconductor chip 200 in the third direction Z that is the vertical direction and the thickness T2 of the second upper wiring portion 144b overlapping the second side surface 200S2 of the semiconductor chip 200 in the third direction Z that is the vertical direction may be greater than the thickness T3 of the third upper wiring portion 146b disposed between the first side surface 200S1 and the second side surface 200S2 of the semiconductor chip 200.

The semiconductor package 10_1 according to FIGS. 10 to 12 may obtain substantially the same effect as that of the semiconductor package 10 according to FIGS. 2 to 4.

In addition, according to the semiconductor package 10_1 according to FIGS. 10 to 12, like the first upper wiring portion 142b overlapping the first side surface 200S1 of the semiconductor chip 200, a thickness of the second upper wiring portion 144b overlapping the second side surface 200S2 of the semiconductor chip 200 may be may be formed relatively thicker than thicknesses of the upper wiring portions disposed between the first and second side surfaces 200S1 and 200S2 of the semiconductor chip 200, so that it is possible to more effectively suppress occurrence of a crack in the second upper wiring portion 144b by improving durability of the second upper wiring portion 144b against the stress generated in the region adjacent to the second side surface 200S2 of the semiconductor chip 200.

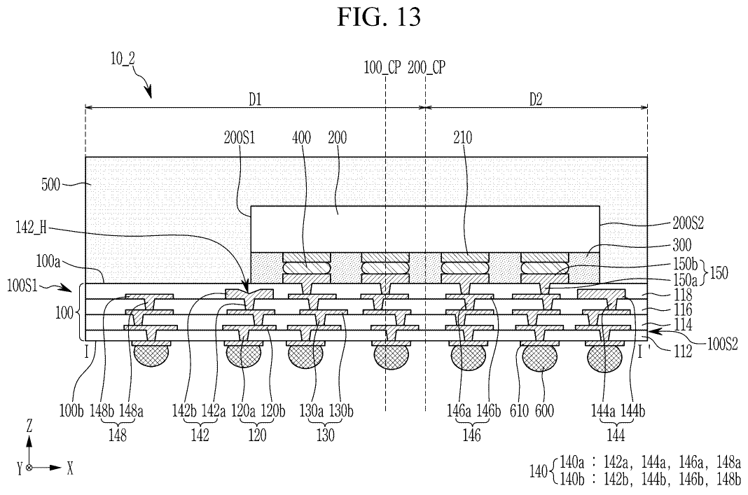

According to the semiconductor package 10_2 according to the embodiment shown in FIG. 13, unlike the embodiment shown in FIG. 10, there is a difference in that the first upper wiring portion 142b of the first upper conductive pattern 142 overlapping the first side surface 200S1 of the semiconductor chip 200 in the third direction Z that is the vertical direction among the upper conductive pattern layer 140 disposed at an uppermost portion of the package substrate 100 further includes the first groove 142_H.

Specifically, in the present embodiment, the first upper wiring portion 142b overlapping the first side surface 200S1 of the semiconductor chip 200 in the third direction Z that is the vertical direction may include the first groove 142_H, and unlike the first upper wiring portion 142b, the second upper wiring portion 144b overlapping the second side surface 200S2 of the semiconductor chip 200 in the third direction Z that is the vertical direction may not include a groove.

Although a shape of the first groove 142_H is shown to have substantially the same shape as that of the first groove 142_H according to the embodiment shown in FIG. 5 in the present embodiment, a shape of the first groove 142_H and the number of the first grooves 142_H are not limited thereto, and may be variously changed. For example, in the present embodiment, the shape and/or the number of the first grooves 142_H may have any one of the shapes of the first groove 142_H according to the embodiment shown in FIG. 6 and FIG. 7.

In addition, in the present embodiment, a position of the first groove 142_H may overlap the first side surface 200S1 of the semiconductor chip 200 in the third direction Z that is the vertical direction, but the position of the first groove 142_H is not limited thereto, and may be variously changed. For example, the position of the first groove 142_H may be substantially the same as the position of the first groove 142_H according to the embodiment shown in FIGS. 8 and 9.

The semiconductor package 10_2 according to FIG. 13 may obtain substantially the same effect as that of the semiconductor package 10_1 according to FIGS. 10 to 12.

In addition, according to the semiconductor package 10_2 according to FIG. 13, even if a crack occurs at some regions of the first upper wiring portion 142b by forming the first groove 142_H at the first upper wiring portion 142b overlapping the first side surface 200S1 of the semiconductor chip 200, the crack may be suppressed from being propagated to another region of the first upper wiring portion 142b by the presence of the first groove 142_H.

In other words, because a size of a stress generated at a region adjacent to the first side surface 200S1 of the semiconductor chip 200 is greater than a size of a stress generated at a region adjacent to the second side surface 200S2 of the semiconductor chip 200, it is possible to suppress occurrence of the crack at an entire region of the first upper wiring portion 142b by forming the first groove 142_H at the first upper wiring portion 142b.

According to the semiconductor package 10_3 according to the embodiment shown in FIGS. 14 to 16, unlike the semiconductor package 10_2 according to the embodiment shown in FIG. 13, there is a difference in that the second upper wiring portion 144b overlapping the second side surface 200S2 of the semiconductor chip 200 in the third direction Z that is the vertical direction among the upper conductive pattern layer 140 disposed at an uppermost portion of the package substrate 100 further includes a second groove 144_H.

Specifically, in the present embodiment, the first upper wiring portion 142b overlapping the first side surface 200S1 of the semiconductor chip 200 in the third direction Z that is the vertical direction may include the first groove 142_H, and the second upper wiring portion 144b overlapping the second side surface 200S2 of the semiconductor chip 200 in the third direction Z that is the vertical direction may include the second groove 144_H.

In the present embodiment, a shape of the first groove 142_H and a shape of the second groove 144_H may be substantially the same. For example, the shape of the first groove 142_H and the shape of the second groove 144_H may have substantially the same shape as the shape of the first groove 142_H according to the embodiment shown in FIG. 5.

Additionally, in the present embodiment, a disposition relationship between the first side surface 200S1 and the first groove 142_H of the semiconductor chip 200 may be substantially the same as a disposition relationship between the second side surface 200S2 and the second groove 144_H of the semiconductor chip 200. For example, the first groove 142_H may overlap the first side surface 200S1 of the semiconductor chip 200 in the third direction Z that is the vertical direction, and the second groove 144_H may overlap the second side surface 200S2 of the semiconductor chip 200 in the third direction Z that is the vertical direction.

In some embodiments, the shape of the first groove 142_H may be different from the shape of the second groove 144_H. For example, the first groove 142_H may have substantially the same shape as that of the first groove 142_H according to the embodiment shown in FIG. 5, and the second groove 144_H may have substantially the same shape as that of the first groove 142_H according to the embodiment shown in FIG. 6. As another example, the first groove 142_H may have substantially the same shape as that of the first groove 142_H according to the embodiment shown in FIG. 6, and the second groove 144_H may have substantially the same shape as that of the first groove 142_H according to the embodiment shown in FIG. 5.

In some embodiments, the number of first grooves 142_H included in the first upper wiring portion 142b may be different from the number of second grooves 144_H included in the second upper wiring portion 144b. For example, the first upper wiring portion 142b may include one first groove 142_H as in the embodiments shown in FIG. 5 and FIG. 6, and the second upper wiring portion 144b may include a plurality of second grooves 144_H as in the embodiments shown in FIG. 7. As another example, the first upper wiring portion 142b may include the plurality of first grooves 142_H as in the embodiment shown in FIG. 7, and the second upper wiring portion 144b may include one second groove 144_H as in the embodiments shown in FIG. 5 and FIG. 6.

In some embodiments, the disposition relationship between the first side surface 200S1 and the first groove 142_H of the semiconductor chip 200 may be different from the disposition relationship between the second side surface 200S2 and the second groove 144_H of the semiconductor chip 200. For example, the first groove 142_H may be disposed outside the first side surface 200S1 of the semiconductor chip 200 and may not overlap the first side surface 200S1 of the semiconductor chip 200 in the third direction Z that is the vertical direction, and the second groove 144_H may overlap the second side surface 200S2 of the semiconductor chip 200 in the third direction Z that is the vertical direction. As another example, the first groove 142_H may overlap the first side surface 200S1 of the semiconductor chip 200 in the third direction Z that is the vertical direction, and the second groove 144_H may be disposed outside the second side surface 200S2 of the semiconductor chip 200 and may not overlap the second side surface 200S2 of the semiconductor chip 200 in the third direction Z that is the vertical direction.

The semiconductor package 10_3 according to FIGS. 14 to 16 may obtain substantially the same effect as that of the semiconductor package 10_1 according to FIGS. 10 to 12.

In addition, according to the semiconductor package 10_3 according to FIGS. 14 to 16, the first groove 142_H may be formed at the first upper wiring portion 142b overlapping the first side surface 200S1 of the semiconductor chip 200 and the second groove 144_H may be formed at the second upper wiring portion 144b overlapping the second side surface 200S2 of the semiconductor chip 200, so that even if a crack occurs at each of some regions of the first upper wiring portion 142b and some regions of the second upper wiring portion 144b, the first groove 142_H and the second groove 144_H may suppress the crack from being propagated to another region of the first upper wiring portion 142b and another region of the second upper wiring portion 144b, respectively.

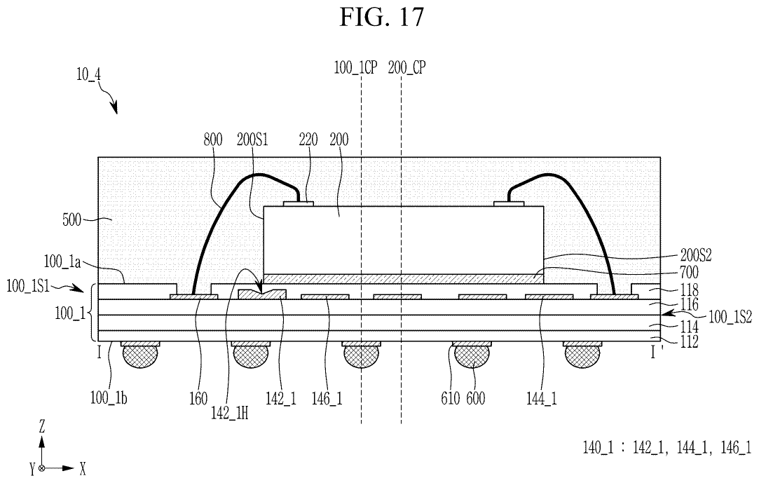

According to the semiconductor package 10_4 according to the embodiment shown in FIG. 17, unlike the embodiment shown in FIGS. 2 to 4, there is a difference in that the semiconductor chip 200 is mounted above a package substrate 100_1 and the package substrate 100_1 and the semiconductor chip 200 are connected by a bonding wire 800.

Referring to FIG. 17, the semiconductor package 10_4 according to the present embodiment may include the package substrate 100_1, the semiconductor chip 200, the molding member 500, the external connection terminal 600, an external connection terminal pad 610, an adhesive member 700, and the bonding wire 800.

Specifically, in the present embodiment, the package substrate 100_1 may be a printed circuit board (PCB). However, the present disclosure is not limited thereto, and in some embodiments, the package substrate 100_1 may be a ceramic substrate, a substrate for a wafer level package (WLP), or a substrate for a package level package (PLP).

The package substrate 100_1 may include a first surface 100_1a and a second surface 100_1b facing each other.

In the present embodiment, the semiconductor chip 200 may be mounted above the first surface 100_1a of the package substrate 100_1 so that it is closer to any one of a first edge 100_1S1 and a second edge 100_1S2 of the package substrate 100_1 facing each other.

In other words, a central axis 200_CP of the semiconductor chip 200 mounted above the package substrate 100_1 and a central axis 100_1CP of the package substrate 100_1 may be misaligned. In other words, because the semiconductor chip 200 is disposed closer to the first edge 100_1S1 or the second edge 100_1S2 of the package substrate 100_1 rather than a central portion of the package substrate 100_1, the semiconductor chip 200 may be mounted biased toward one side or the other side of the package substrate 100_1.

For example, the semiconductor chip 200 may be mounted above the package substrate 100_1 so that it is closer to the second edge 100_1S2 of the package substrate 100_1. That is, because the central axis 200_CP of the semiconductor chip 200 is disposed to be spaced apart from the central axis 100_1CP of the package substrate 100_1 along the first direction X, the central axis 200_CP of the semiconductor chip 200 may be disposed closer to the second edge 100_1S2 of the package substrate 100_1 than to the first edge 100_1S1 of the package substrate 100_1.

The package substrate 100_1 may include the first to fourth insulating layers 112, 114, 116, and 118 sequentially stacked, a plurality of conductive patterns 140_1, and a bonding pad 160.

Because the description of the first to fourth insulating layers 112, 114, 116, and 118 of the semiconductor package 10 according to the embodiment is substantially and equally applied to the first to fourth insulating layers 112, 114, 116, and 118 of the semiconductor package 10_4 according to the present embodiment, a description thereof is omitted.

Specifically, the plurality of conductive patterns 140_1 may include a first conductive pattern 142_1, a second conductive pattern 144_1, and a third conductive pattern 146_1 disposed at an uppermost portion of the package substrate 100_1. That is, the first conductive pattern 142_1, the second conductive pattern 144_1, and the third conductive pattern 146_1 may be disposed on an upper surface of the third insulating layer 116, and may be covered by the fourth insulating layer 118.

Although FIG. 17 shows that the package substrate 100_1 includes one conductive pattern, the number of conductive patterns included in the package substrate 100_1 is not limited thereto, and may be variously changed. For example, the package substrate 100_1 may further include a conductive pattern disposed on an upper surface of the first insulating layer 112 and/or an upper surface of the second insulating layer 114.

If the package substrate 100_1 further includes the conductive pattern disposed on the upper surface of the first insulating layer 112 and/or the upper surface of the second insulating layer 114, at least a portion of the plurality of conductive patterns disposed within the package substrate 100_1 may be connected through a conductive via penetrating the first to fourth insulating layers 112, 114, 116, and 118.

Descriptions of the disposition relationship between the upper conductive wiring portions 142b, 144b, and 146b of the semiconductor packages 10_1, 10_2, and 10_3 according to some embodiments and the semiconductor chip 200, the thickness relationship between the upper conductive wiring portions 142b, 144b, and 146b, and the shapes of the upper conductive wiring portions 142b, 144b, and 146b may be substantially and equally applied to a disposition relationship between the plurality of conductive patterns 140_1 according to the present embodiment and the semiconductor chip 200, a thickness relationship between the plurality of conductive patterns 140_1, and shapes of the plurality of conductive patterns 140_1.

Specifically, the first conductive pattern 142_1 may overlap the first side surface 200S1 of the semiconductor chip 200 in the third direction Z that is the vertical direction, and the second conductive pattern 144_1 may overlap the second side surface 200S2 of the semiconductor chip 200 in the third direction Z that is the vertical direction.

A portion of the first conductive pattern 142_1 may be disposed outside the first side surface 200S1 of the semiconductor chip 200 when viewed in plan view, and the remaining portion of the first conductive pattern 142_1 may be disposed inside the first side surface 200S1 of the semiconductor chip 200 when viewed in plan view.

A portion of the second conductive pattern 144_1 may be disposed outside the second side surface 200S2 of the semiconductor chip 200 when viewed in plan view, and the remaining portion of the second conductive pattern 144_1 may be disposed inside the second side surface 200S2 of the semiconductor chip 200 when viewed in plan view.

In the present embodiment, the conductive pattern 140_1 may include a plurality of third conductive patterns 146_1 disposed between the first side surface 200S1 and the second side surface 200S2 of the semiconductor chip 200.

The third conductive pattern 146_1 may be disposed between the first side surface 200S1 and the second side surface 200S2 of the semiconductor chip 200 when viewed in plan view, and may completely overlap the semiconductor chip 200 in the third direction Z that is the vertical direction. In other words, the first conductive pattern 142_1 may be disposed at one side of the first direction X of the third conductive patterns 146_1 and the second conductive pattern 144_1 may be disposed at the other side of the first direction X, so that the third conductive patterns 146_1 is disposed between the first conductive pattern 142_1 and the second conductive pattern 144_1. For example, the third conductive pattern 146_1 may be disposed beneath the semiconductor chip 200.

The first to third conductive patterns 142_1, 144_1, and 146_1 may be connected to any one of configurations (or components) disposed within the package substrate 100_1 and configurations disposed on the first surface 100_1a and the second surface 100_1b of the package substrate 100_1, and may form a pad or a wire of the package substrate 100_1.

In the present embodiment, a thickness of the first conductive pattern 142_1 may be thicker than a thickness of the second conductive pattern 144_1 and a thickness of the third conductive pattern 146_1. The thickness of the second conductive pattern 144_1 and the thickness of the third conductive pattern 146_1 may be substantially the same. However, a thickness relationship between the first to third conductive patterns 142_1, 144_1, and 146_1 is not limited thereto, and may be variously changed. For example, the thickness of the first conductive pattern 142_1 and the thickness of the second conductive pattern 144_1 may be substantially the same, and the thickness of the third conductive pattern 146_1 may be thinner than the thickness of the first conductive pattern 142_1 and the thickness of the second conductive pattern 144_1.

In the present embodiment, the first conductive pattern 142_1 may include a first groove 142_1H recessed from an upper surface thereof toward a lower surface thereof. The first groove 142_1H may have a recessed shape from an upper surface of the first conductive pattern 142_1 toward a lower surface thereof on a cross-section. The first groove 142_1H may overlap the first side surface 200S1 of the semiconductor chip 200 in the third direction Z that is the vertical direction. However, a shape and a position of the first groove 142_1H according to the embodiment shown in FIG. 17 are not limited thereto, and may be variously changed. For example, the first groove 142_1H of the first conductive pattern 142_1 may have substantially the same shape as that of the first groove 142_H of the first upper wiring portion 142b according to some embodiments described above with reference to FIGS. 5 to 7. As another example, the first groove 142_1H of the first conductive pattern 142_1 may be disposed outside the first side surface 200S1 of the semiconductor chip 200, and may not overlap the semiconductor chip 200 in the third direction Z that is the vertical direction.

Additionally, in some embodiments, the first conductive pattern 142_1 may not include the first groove 142_1H. That is, the upper portion surface of the first conductive pattern 142_1 may have a flat surface.

In some embodiments, the second conductive pattern 144_1 may further include a second groove (not shown). Descriptions of the shape and the position of the second groove 144_H of the second upper wiring portion 144b and the relationship between the second groove 144_H and the first groove 142_H included in the first upper wiring portion 142b according to the above-described embodiment with reference to FIGS. 14 to 16 may be substantially and equally applied to the second groove of the second conductive pattern 144_1.

The bonding pad 160 may be disposed at substantially the same level as that of the plurality of conductive patterns 140_1, and the bonding pad 160 may be disposed outside each of the first side surface 200S1 and the second side surface 200S2 of the semiconductor chip 200 when viewed in plan view. That is, the bonding pad 160 may be disposed outside the first conductive pattern 142_1 and outside the second conductive pattern 144_1, respectively.

The bonding pad 160 may overlap an opening recessed from an upper surface of the fourth insulating layer 118 to a lower surface thereof in the third direction Z that is the vertical direction. That is, a portion of the bonding pad 160 may be exposed by the opening of the fourth insulating layer 118.

In the present embodiment, a thickness of the bonding pad 160 may be thinner than the thickness of the first conductive pattern 142_1, and may be substantially the same as the thickness of the second conductive pattern 144_1 and the thickness of the third conductive pattern 146_1. However, a thickness relationship between the bonding pad 160 and the first to third conductive patterns 142_1, 144_1, and 146_1 is not limited thereto, and may be variously changed.

The first conductive pattern 142_1, the second conductive pattern 144_1, the third conductive pattern 146_1, and the bonding pad 160 may include a conductive material. For example, the conductive material may include copper (Cu). However, a material included in the first conductive pattern 142_1, the second conductive pattern 144_1, the third conductive pattern 146_1, and the bonding pad 160 are not limited thereto, and may be variously changed.

The semiconductor chip 200 may include a plurality of chip pads 220. A chip pad 220 may be disposed on an upper surface of the semiconductor chip 200. For example, the chip pad 220 may be disposed at one or more edges of the upper surface of the semiconductor chip 200.

The chip pad 220 may include a conductive material. For example, the chip pad 220 may include any one of copper (Cu), aluminum (Al), titanium (Ti), chromium (Cr), iron (Fe), cobalt (Co), nickel (Ni), zinc (Zn), lead Pd), platinum (Pt), gold (Au), silver (Ag), and a combination thereof. However, a material included in the chip pad 220 is not limited thereto, and may be variously changed.

The bonding wire 800 may be connected to the bonding pad 160 of the package substrate 100_1 and the chip pad 220 of the semiconductor chip 200. Accordingly, the package substrate 100_1 and the semiconductor chip 200 may be electrically connected to each other.

The adhesive member 700 may be disposed between the package substrate 100_1 and the semiconductor chip 200. A length of the adhesive member 700 along the first direction X may be substantially the same as a length of the semiconductor chip 200 along the first direction X, but embodiments are not limited thereto.

The adhesive member 700 may fix the semiconductor chip 200 above the package substrate 100_1. For example, the adhesive member 700 may be a die attach film (DAF), but the present disclosure is not limited thereto.

The bonding wire 800 may include a conductive material. For example, the bonding wire 800 may include silver (Ag), copper (Cu), gold (Au), aluminum (Al), or the like. However, a material included in the bonding wire 800 is not limited thereto, and may be variously changed.

The molding member 500 may be disposed on the first surface 100_1a of the package substrate 100_1. The molding member 500 may entirely cover the package substrate 100_1, the semiconductor chip 200, the chip pad 220, the adhesive member 700, and the bonding wire 800.

The molding member 500 may be disposed within the opening of the fourth insulating layer 118. The molding member 500 may cover the bonding pad 160 disposed within the opening of the fourth insulating layer 118.

The molding member 500 may include an insulating material. For example, the molding member 500 may include an insulating polymer such as an epoxy-based molding compound (EMC). However, a material included in the molding member 500 is not limited thereto, and may be variously changed.

The plurality of external connection terminals 600 may be disposed on the second surface 100_1b of the package substrate 100_1. The external connection terminal pad 610 may be disposed between the package substrate 100_1 and the external connection terminal 600 on the second surface 100_1b of the package substrate 100_1.

For example, the external connection terminal 600 may be at least one of a solder ball, a pillar, and a bump. However, a type of the external connection terminal 600 is not limited thereto, and may be variously changed.

The external connection terminal 600 may be connected to the bonding pad 160 of the package substrate 100_1. The external connection terminal 600 may electrically connect the semiconductor package 10_4 according to the present embodiment to an external electronic device or the semiconductor packages 10_1, 10_2, and 10_3 according to some embodiments.

The semiconductor package 10_4 according to the present embodiment may have substantially the same effect as that of the semiconductor packages 10_1, 10_2, and 10_3 according to some embodiment.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the inventive concept.

What is claimed is:

1. A semiconductor package comprising:
a package substrate that includes an insulating layer and a plurality of conductive patterns within the insulating layer, each of the plurality of conductive patterns including a respective wiring portion and a respective via portion;
a semiconductor chip on the package substrate and connected to the plurality of conductive patterns; and
a molding member that covers the package substrate and the semiconductor chip,
wherein the semiconductor chip is closer to a second edge than to a first edge of the package substrate opposite to the second edge,
wherein the plurality of conductive patterns includes a first conductive pattern overlapping a first side surface of the semiconductor chip in a vertical direction and a second conductive pattern overlapping a second side surface of the semiconductor chip in a vertical direction, and
wherein a thickness in the vertical direction of a wiring portion of the first conductive pattern is different from a thickness in the vertical direction of a wiring portion of the second conductive pattern.

2. The semiconductor package of claim 1, wherein a separation distance between the first edge of the package substrate and the first side surface of the semiconductor chip is greater than a separation distance between the second edge of the package substrate and the second side surface of the semiconductor chip, and
wherein the thickness of the wiring portion of the first conductive pattern is greater than the thickness of the wiring portion of the second conductive pattern.

3. The semiconductor package of claim 2, wherein the first conductive pattern includes a first groove recessed toward a bottom surface of the package substrate.

4. The semiconductor package of claim 3, wherein the first groove of the first conductive pattern has a V-shape or a U-shape in a cross-section.

5. The semiconductor package of claim 4, wherein the first groove of the first conductive pattern is outside the first side surface of the semiconductor chip when viewed in plan view.

6. The semiconductor package of claim 4, wherein a portion of the first groove of the first conductive pattern is outside the first side surface of the semiconductor chip when viewed in plan view, and the remaining portion of the first groove of the first conductive pattern is inside the first side surface of the semiconductor chip when viewed in plan view.

7. The semiconductor package of claim 2, wherein a portion of an upper surface of the first conductive pattern is uneven.

8. The semiconductor package of claim 7, wherein the uneven portion of the upper surface of the first conductive pattern is outside the first side surface of the semiconductor chip when viewed in plan view.

9. The semiconductor package of claim 2, wherein the plurality of conductive patterns further includes a third conductive pattern between the first side surface and the second side surface of the semiconductor chip, and a thickness of the wiring portion of the third conductive pattern is substantially the same as the thickness of the wiring portion of the second conductive pattern.

10. The semiconductor package of claim 9, wherein the plurality of conductive patterns further includes a fourth conductive pattern outside the first side surface or the second side surface of the semiconductor chip, and the thickness of the wiring portion of the fourth conductive pattern is substantially the same as the thickness of the wiring portion of the second conductive pattern and the thickness of the wiring portion of the third conductive pattern.

11. The semiconductor package of claim 2, further comprising:
a bonding pad outside the first side surface and the second side surface of the semiconductor chip;
a bonding wire that connects the bonding pad to the semiconductor chip; and
a connection terminal on a second surface of the package substrate opposite to a first surface of the package substrate.

12. The semiconductor package of claim 1, wherein the plurality of conductive patterns includes copper (Cu), and the molding member is an epoxy mold compound (EMC).

13. A semiconductor package comprising:
a package substrate that includes an insulating layer and a plurality of conductive patterns within the insulating layer, each of the plurality of conductive patterns including a respective wiring portion and a respective via portion;
a semiconductor chip on the package substrate and connected to the plurality of conductive patterns; and
a molding member that covers the package substrate and the semiconductor chip,
wherein the semiconductor chip is closer to a second edge of the package substrate than to a first edge of the package substrate opposite to the second edge,
wherein conductive patterns disposed at an uppermost portion among the plurality of conductive patterns include a first conductive pattern overlapping a first side surface of the semiconductor chip in a vertical direction, a second conductive pattern overlapping a second side surface of the semiconductor chip in the vertical direction, and a third conductive pattern between the first side surface and the second side surface of the semiconductor chip when viewed in plan view,
wherein at least one of a thickness of a wiring portion of the first conductive pattern and a thickness of a wiring portion of the second conductive pattern is greater than a thickness of a wiring portion of the third conductive pattern, and
wherein the first conductive pattern includes a first groove recessed toward a bottom surface of the package substrate.

14. The semiconductor package of claim 13, wherein the thickness of the wiring portion of the first conductive pattern is greater than the thickness of the wiring portion of the second conductive pattern and the thickness of the wiring portion of the third conductive pattern.

15. The semiconductor package of claim 14, wherein the thickness of the wiring portion of the second conductive pattern is greater than the thickness of the wiring portion of the third conductive pattern.

16. The semiconductor package of claim 15, wherein the second conductive pattern includes a second groove recessed toward a bottom surface of the package substrate.

17. The semiconductor package of claim 16, wherein each of the first groove of the first conductive pattern and the second groove of the second conductive pattern has a V-shape or a U-shape in a cross-section.

18. The semiconductor package of claim 16, wherein each of the first conductive pattern and the second conductive pattern includes a respective base portion and a respective plurality of protruding portions on the base portion, and
wherein the first groove of the first conductive pattern and the second groove of the second conductive pattern are defined by the plurality of protruding portions adjacent to each other and an upper surface of the base portion.

19. The semiconductor package of claim 16, wherein the first groove of the first conductive pattern is outside the first side surface of the semiconductor chip when viewed in plan view, and the second groove of the second conductive pattern is outside the second side surface of the semiconductor chip when viewed in plan view.

20. A semiconductor package comprising:
a package substrate that includes an insulating layer and a plurality of conductive patterns within the insulating layer, each of the plurality of conductive patterns including a respective wiring portion and a respective via portion;
a semiconductor chip on the package substrate and connected to the plurality of conductive patterns;
a molding member that covers the package substrate and the semiconductor chip;
a bonding pad on a first surface of the package substrate facing the semiconductor chip, the bonding pad being connected to the plurality of conductive patterns;
a first connection terminal between the semiconductor chip and the package substrate, the first connection terminal connecting the semiconductor chip to the bonding pad; and
a second connection terminal on a second surface opposite to the first surface of the package substrate, the second connection terminal being connected to the plurality of conductive patterns,
wherein the semiconductor chip is closer to a second edge of the package substrate opposite to a first edge of the package substrate,
wherein conductive patterns disposed at an uppermost portion among the plurality of conductive patterns include a first conductive pattern overlapping a first side surface of the semiconductor chip in a vertical direction, a second conductive pattern overlapping a second side surface of the semiconductor chip in a vertical direction, and a third conductive pattern between the first side surface and the second side surface of the semiconductor chip, the third conductive pattern being connected to the bonding pad,
wherein a thickness of a wiring portion of the first conductive pattern is greater than a thickness of a wiring portion of the second conductive pattern and a thickness of a wiring portion of the third conductive pattern,
wherein the thickness of the wiring portion of the second conductive pattern and the thickness of the wiring portion of the third conductive pattern are substantially the same, and
wherein the first conductive pattern includes a first groove recessed toward a bottom surface of the package substrate.
